(19) United States
(12) Patent Application Publication
(10) Pub. No.: US 2014/0252626 A1
(43) Pub. Date: Sep. 11, 2014

(54) SEMICONDUCTOR PACKAGE AND METHOD OF FABRICATING THE SAME

(71) Applicant: SAMSUNG ELECTRONICS CO., LTD., SUWON-SI (KR)

(72) Inventors: Un-Byoung KANG, Hwaseong-si (KR); Hyuek-Jae LEE, Hwaseong-si (KR); Chung-Sun LEE, Anyang-si (KR)

(73) Assignee: SAMSUNG ELECTRONICS CO., LTD., SUWON-SI (KR)

(21) Appl. No.: 14/204,091

(22) Filed: Mar. 11, 2014

(30) Foreign Application Priority Data
Mar. 11, 2013 (KR) 10-2013-0025772

(51) Int. Cl. H01L 25/04; H01L 21/768; H01L 25/00; H01L 23/00; H01L 23/538

(52) U.S. Cl. CPC H01L 25/04; H01L 24/26; H01L 23/5386; H01L 25/50; H01L 21/76843
USPC 257/751; 438/109

(57) ABSTRACT

A semiconductor package and a method for fabricating the same are provided. The semiconductor package includes a wafer, a plurality of semiconductor chips each having a connection pad and being stacked on the wafer, resin layers formed to expose top surfaces of the connection pads and to cover lateral surfaces and top surfaces of the semiconductor chips, through lines formed in at least one side of opposite sides of each of the semiconductor chips, to be spaced apart from the semiconductor chips, and to extend in a first direction, and redistribution lines arranged between the through lines, formed to extend in a second direction on the resin layers, and connected to the connection pads, wherein the through lines and the redistribution lines include barrier layers formed on lateral surfaces and bottom surfaces of the through lines and the redistribution lines, and conductive layers formed on the barrier layers.

### CROSS-REFERENCE TO RELATED APPLICATIONS

This application claims the benefit of priority under 35 U.S.C. §119 to Korean Patent Application No. 10-2013-0025772, filed on Mar. 11, 2013, in the Korean Intellectual Property Office, the content of which is incorporated herein in its entirety by reference.

### BACKGROUND

1. Field

The present general inventive concept relates to a semiconductor package and method of fabricating the same.

2. Description of the Related Art

One of the primary concerns in the semiconductor industry is how to fabricate small-sized, multi-functional, high-capacity, high-reliability semiconductor products at low costs. Semiconductor packaging is among the important technologies for achieving such aspirational goals. Among various semiconductor packaging technologies, a stacked semiconductor packaging process in which a plurality of chips is stacked is being proposed as a possible option to realize the desired objectives.

### SUMMARY

An embodiment of the present general inventive concept provides a method of fabricating a semiconductor package, which may improve a processing speed while reducing a cost of fabrication.

An embodiment of the present general inventive concept also provides a semiconductor package, which may improve a processing speed while reducing a cost of fabrication.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a semiconductor package that includes a wafer, a plurality of semiconductor chips each having a connection pad and being stacked on the wafer, a plurality of resin layers formed to expose top surfaces of the connection pads and to cover lateral surfaces and top surfaces of the plurality of semiconductor chips, a plurality of through lines formed in at least one side of opposite sides of each of the plurality of semiconductor chips, to be spaced apart from the plurality of semiconductor chips, and to extend in a first direction, and a plurality of redistribution lines arranged between the plurality of through lines, formed to extend in a second direction on the resin layers, and connected to the connection pads, wherein the plurality of through lines and the plurality of redistribution lines include barrier layers formed on lateral surfaces and bottom surfaces of the through lines and the redistribution lines, and conductive layers formed on the barrier layers.

The first direction and the second direction may be perpendicular to each other.

The semiconductor package may further include a plurality of insulation layers formed on bottom surfaces of the plurality of semiconductor chips.

The semiconductor package may further include adhesive layers formed between the insulation layers and the semiconductor chips.

Of the plurality of insulation layers, an insulation layer may be formed on a top surface of the wafer includes a thermal interface material.

At least one of the plurality of redistribution lines may include a first sub-redistribution line and a second sub-redistribution line, and the barrier layers may be formed on the lateral surfaces and the bottom surfaces of the first sub-redistribution line and the second sub-redistribution line.

The through lines and the redistribution lines may include copper.

The barrier layers may include titanium.

The foregoing and/or other features and utilities of the present general inventive concept may also be achieved by providing a method of fabricating a semiconductor package that includes providing a first semiconductor chip connected to a first redistribution line, forming a first insulation layer that exposes a portion of a top surface of the first redistribution line, forming a second semiconductor chip on the first insulation layer, the second semiconductor chip having a first connection pad arranged on a top surface of the second semiconductor chip, forming a first resin layer that covers the second semiconductor chip and exposes the portion of the top surface of the first redistribution line and a top surface of the first connection pad, forming, on the first resin layer, a second resin layer that exposes the portion of the top surface of the first redistribution line, the top surface of the first connection pad, and the first resin layer between the top surface of the first redistribution line and the first connection pad, forming through lines on the top surface of the first redistribution line, and forming a second redistribution line on the through lines, the top surface of the first connection pad and the first resin layer.

The through lines may not overlap the first semiconductor chip and the second semiconductor chip.

The forming the through lines and the forming the second redistribution line may include forming a barrier layer on the portion of the top surface of the first redistribution line and the top surface of the first connection pad, and forming a conductive layer on the barrier layer.

The second redistribution line may include a first sub-redistribution line and a second sub-redistribution line, and the forming the through lines and the forming the second redistribution line may further include, after the forming the first resin layer, forming the through lines on the top surface of the first redistribution line and forming the first sub-redistribution line on the top surface of the first connection pad, and, after the forming the second resin layer, forming the through lines on the first sub-redistribution line and the third resin layer.

Before the providing the first semiconductor chip, the method may further include forming a second insulation layer on the wafer, forming the first semiconductor chip on the second insulation layer, the first semiconductor chip having a second connection pad arranged on a top surface of the first semiconductor chip, forming a third resin layer that covers the first semiconductor chip and exposes a top surface of the second connection pad, forming, on the third resin layer, a fourth resin layer that exposes the top surface of the second connection pad and a portion of a top surface of the third resin layer, and forming the first redistribution line on the top surface of the second connection pad and a top surface of the third resin layer.

The method may further include, after the forming the second insulation layer, forming a first adhesive layer on the second insulation layer, and, after the forming the first insulation layer, forming a second adhesive layer on the first insulation layer.

The first redistribution line includes a third sub-redistribution line and a fourth sub-redistribution line, and the forming the first redistribution line includes forming the third sub-redistribution line on the top surface of the second connection pad after the forming the third resin layer, and forming the fourth sub-redistribution line on the top surface of the third resin layer after the forming the fourth resin layer.

The foregoing and/or other features and utilities of the present general inventive concept may also be achieved by providing a semiconductor package that includes a first semiconductor chip formed on a wafer and connected to a first redistribution line, a second semiconductor chip formed on the first semiconductor chip and connected to a second redistribution line, and a through line spaced apart from the first semiconductor chip and the second semiconductor chip and connected to the first redistribution line and the second redistribution line so that at least one of the first redistribution line, the second distribution line, and the through line includes a barrier layer on all surfaces except for an upper surface.

The barrier layer may include titanium.

At least one of the first semiconductor chip and the second semiconductor chip may exclude a through-silicon via.

At least one of the first semiconductor chip and the second semiconductor chip may be formed on an adhesive layer and may include a resin layer on all surfaces of the at least one of the first semiconductor chip and the second semiconductor chip except for an upper surface of the at least one of the first semiconductor chip and the second semiconductor chip. The adhesive layer may be formed on an insulation layer.

At least one of the first redistribution line and the second redistribution line may include a first sub-redistribution line and a second sub-redistribution line. Each of the first sub-redistribution line and the second sub-redistribution line may include the barrier layer on all surfaces of each of the first sub-redistribution line and the second sub-redistribution line except for an upper surface of each of the first sub-redistribution line and the second sub-redistribution line.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a cross-sectional view of a semiconductor package according to an embodiment of the inventive concept;

FIG. 2 is a cross-sectional view of a semiconductor package according to an embodiment of the inventive concept;

FIGS. 3 to 20 illustrate intermediate process operations that explain a method of fabricating a semiconductor package according an embodiment of the inventive concept;

FIGS. 21 to 24 illustrate intermediate process operations that explain a method of fabricating a semiconductor package according an embodiment of the inventive concept;

FIG. 25 is a block diagram illustrating a memory card that incorporates semiconductor packages according to an embodiment of the inventive concept;

FIG. 26 is a block diagram illustrating an electronic system that incorporates a semiconductor package according to an embodiment of the inventive concept; and

FIG. 27 illustrates an example of an electronic system used for a smart phone.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. The present general inventive concept may, however, be embodied in different forms and should not be construed as limited to the embodiments set forth herein. Rather, these embodiments are provided so that this disclosure is thorough and complete, and fully conveys the scope of the present general inventive concept to those skilled in the art. In the attached figures, the thickness of layers and regions may be exaggerated for clarity.

The use of the terms “a” and “an” and “the” and similar referents in the context of describing the present general inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It is also understood that when a layer is referred to as being “on” another layer or substrate, it may be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper,” and the like, may be used herein for ease of description to describe one element or feature's relationship to another element(s) or feature(s) as illustrated in the figures. It is understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

It is understood that, although the terms first, second, etc. may be used herein to describe various elements, these elements should not be limited by these terms. These terms are only used to distinguish one element from another element. Thus, for example, a first element, a first component, or a first section discussed below could be termed a second element, a second component, or a second section without departing from the teachings of the present general inventive concept.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the present general inventive concept and is not a limitation on the scope of the present general inventive concept unless otherwise specified. Further, unless defined otherwise, all terms defined in generally used dictionaries may not be overly interpreted.

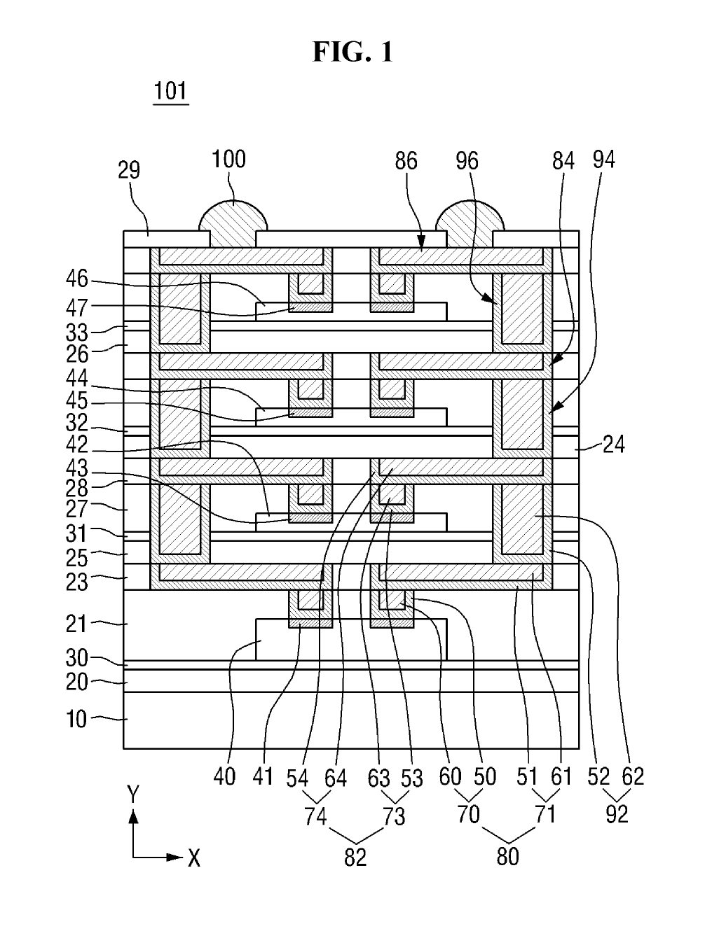

Hereinafter, a semiconductor package 101 according to an embodiment of the inventive concept is described with reference to FIG. 1.

FIG. 1 is a cross-sectional view of the semiconductor package 101 according to an embodiment of the inventive concept.

Referring to FIG. 1, the semiconductor package 101 may include a wafer 10, a plurality of semiconductor chips 40, 42, 44, and 46, a plurality of resin layers 21, 23, 27, 28, and 29, a plurality of through lines 92, 94, and 96, and a plurality of redistribution lines 80, 82, 84, and 86.

The plurality of semiconductor chips 40, 42, 44, and 46 may be arranged on the wafer 10. The plurality of semiconductor chips 40, 42, 44 and 46 may be sequentially stacked in a first direction (Y-axis direction). For example, the first semiconductor chip 40 may be arranged on the wafer 10, the second semiconductor chip 42 may be arranged on the first semiconductor chip 40, the third semiconductor chip 44 may be arranged on the second semiconductor chip 42, and the fourth semiconductor chip 46 may be arranged on the third semiconductor chip 44. The first to fourth semiconductor chips 40, 42, 44, and 46 may be, for example, flip chips. In an embodiment of the present general inventive concept, the four semiconductor chips 40, 42, 44, and 46 may be arranged on the wafer 10, but aspects of the present general inventive concept are not limited thereto. More than or fewer than four semiconductor chips may be stacked on the wafer 10. The plurality of semiconductor chips 40, 42, 44, and 46, which may be connected to an external device (not illustrated) may include, respectively, connection pads 41, 43, 45, and 47 to transmit/receive electrical signals or power to/from the external device. The connection pads 41, 43, 45, and 47 may be arranged in the same direction in order to facilitate stacking of the plurality of semiconductor chips 40, 42, 44, and 46 and testing of the semiconductor package 101. For example, as illustrated in FIG. 1, the connection pads 41, 43, 45, and 47 may be formed on top surfaces of the plurality of semiconductor chips 40, 42, 44, and 46, but aspects of the present general inventive concept are not limited thereto. That is to say, the connection pads 41, 43, 45, and 47 may also be arranged on bottom surfaces of the plurality of semiconductor chips 40, 42, 44, and 46.

The plurality of semiconductor chips 40, 42, 44, and 46 may be, for example, memory chips or logic chips. In a case where the plurality of semiconductor chips 40, 42, 44, and 46 are logic chips, the plurality of semiconductor chips 40, 42, 44, and 46 may be designed in various manners in consideration of operations to be executed. For example, a logic chip may be a microprocessor, such as a central processing unit (CPU), a controller, or an application specific integrated circuit (ASIC). In a case where the plurality of semiconductor chips 40, 42, 44, and 46 are memory chips, the memory chips may be, for example, a volatile memory such as dynamic random-access memory (DRAM) or static random-access memory (SRAM), or a nonvolatile memory such as a flash memory. For example, the memory chips may be flash memory chips. In another example, the memory chips may be “Not AND” logic circuit-based (NAND) flash memory chips or “Not OR” logic circuit-based (NOR) flash memory chips, but aspects of the present general inventive concept are not limited thereto. In an embodiment of the present general inventive concept, the memory chip may include, for example, one of a phase-change random-access memory (PRAM), a magneto-resistive random-access memory (MRAM), and a resistive random-access memory (RRAM).

The plurality of semiconductor chips 40, 42, 44, and 46 may be chips of the same type, and/or may be chips of different types. For example, the first semiconductor chip 40 may be a logic chip, and the second, third, and fourth semiconductor chips 42, 44, and 46 may be memory chips. In addition, the plurality of semiconductor chips 40, 42, 44 and 46 illustrated in FIG. 1 have the same size, but aspects of the present general inventive concept are not limited thereto. The plurality of semiconductor chips 40, 42, 44, and 46 may have different sizes.

The wafer 10 may be made, for example, of a semiconductor material or an insulating material. That is to say, in an embodiment of the present inventive concept, the wafer 10 may include, for example, silicon (Si), germanium (Ge), silicon-germanium (SiGe), gallium-arsenic (GaAs), glass, ceramic, or the like. A thickness of the wafer 10 may be adjusted as desired, which is described below.

The plurality of semiconductor chips 40, 42, 44, and 46 may be formed on a plurality of insulation layers 20, 25, 24, and 26. The plurality of insulation layers 20, 25, 24, and 26 may separate the plurality of semiconductor chips 40, 42, 44, and 46 from each other and may separate the plurality of redistribution lines 80, 82, 84, and 86 from the plurality of semiconductor chips 40, 42, 44, and 46, and may be provided to stack the plurality of semiconductor chips 40, 42, 44, and 46.

Adhesive layers 30, 31, 32, and 33 may be formed between the plurality of insulation layers 20, 25, 24, and 26 and the plurality of semiconductor chips 40, 42, 44, and 46. The adhesive layers 30, 31, 32, and 33 may fix the plurality of semiconductor chips 40, 42, 44, and 46 on the plurality of insulation layers 20, 25, 24, and 26 to prevent the plurality of semiconductor chips 40, 42, 44, and 46 from vibrating during the course of fabricating the semiconductor package 101.

Among the plurality of insulation layers 20, 25, 24, and 26, the first insulation layer 20 formed between the wafer 10 and the first semiconductor chip 40 may include a thermal interface material (TIM). The TIM may be, for example, a curable adhesive material including a metal, such as silver (Ag), or metal oxide based particles, such as alumina (Al₂O₃), applied on an epoxy resin, or thermal grease including particles of diamond, aluminum nitride (AlN), alumina (Al₂O₃), zinc oxide (ZnO), or silver (Ag). If the first insulation layer 20 includes TIM, heat generated from the plurality of semiconductor chips 40, 42, 44, and 46 may be rapidly discharged to the outside.

The plurality of semiconductor chips 40, 42, 44, and 46 may be electrically connected to each other or the external device (not illustrated) through the plurality of redistribution lines 80, 82, 84, and 86 and the plurality of through lines 92, 94, and 96. For example, the first semiconductor chip 40 may be electrically connected to the first redistribution line 80 through the first connection pad 41, the second semiconductor chip 42 may be electrically connected to the second redistribution line 82 through the second connection pad 43, the third semiconductor chip 44 may be electrically connected to the third redistribution line 84 through the third connection pad 45, and the fourth semiconductor chip 46 may be electrically connected to the fourth redistribution line 86 through the fourth connection pad 47. The plurality of redistribution lines 80, 82, 84, and 86 may extend in a second direction (X-axis direction) to be electrically connected to the plurality of through lines 92, 94, and 96. For example, the first redistribution line 80 may be connected to a bottom surface of the first through line 92, and the second redistribution line 82, arranged between the first through line 92 and the second through line 94, may be connected to the first through line 92 and the second through line 94. The third redistribution line 84 may be arranged between the second through line 94 and the third through line 96 to be connected to the second through line 94 and the third through line 96. The fourth redistribution line 86 may be connected to a top surface of the third through line 96 and may be connected to bumps 100. Here, the bumps 100 may be, for example, solder balls, and may be attached to the fourth redistribution line 86 by a thermal compression process and/or a reflow process.

The plurality of through lines 92, 94, and 96 may be electrically connected to the plurality of redistribution lines 80, 82, 84, and 86 to transmit electrical signals. The plurality of through lines 92, 94, and 96 may extend in the first direction (Y-axis direction) in a line. Therefore, the plurality of through lines 92, 94, and 96 may be formed in at least one side of opposite sides of each of the plurality of semiconductor chips 40, 42, 44, and 46 to be spaced apart from the plurality of semiconductor chips 40, 42, 44, and 46. For example, the first through line 92 may not overlap the first and second semiconductor chips 40 and 42. The plurality of through lines 92, 94, and 96 may be vertically connected to the plurality of redistribution lines 80, 82, 84, and 86.

The plurality of through lines 92, 94, and 96 and the plurality of redistribution lines 80, 82, 84, and 86 may include two layers. For example, the plurality of through lines 92, 94, and 96 and the plurality of redistribution lines 80, 82, 84, and 86 may include barrier layers 50, 51, 52, 53, and 54 and, respectively, conductive layers 60, 61, 62, 63, and 64. The barrier layers 50, 51, 52, 53, and 54 may be conformally formed on lateral surfaces and bottom surfaces of the plurality of through lines 92, 94, and 96 and the plurality of redistribution lines 80, 82, 84, and 86, and the conductive layers 60, 61, 62, 63, and 64 may be formed on the barrier layers 50, 51, 52, 53, and 54 to fill the plurality of through lines 92, 94, and 96 and the plurality of redistribution lines 80, 82, 84, and 86.

If the conductive layers 60, 61, 62, 63, and 64 are directly formed without forming the barrier layers 50, 51, 52, 53, and 54, there may be no layers functioning as seeds, making it difficult to form the conductive layers 60, 61, 62, 63, and 64, for example, due to voids created in the conductive layers 60, 61, 62, 63, and 64. In addition, if the conductive layers 60, 61, 62, 63, and 64 are directly formed, they may penetrate into the plurality of insulation layers 20, 25, 24, and 26 and the plurality of resin layers 21, 23, 27, 28, and 29, resulting in a malfunction of the semiconductor package 101. Therefore, forming of the conductive layers 60, 61, 62, 63, and 64 may be facilitated by forming the barrier layers 50, 51, 52, 53, and 54, and the malfunction of the semiconductor package 101 may be prevented by preventing the conductive layers 60, 61, 62, 63, and 64 from penetrating into the plurality of insulation layers 20, 25, 24, and 26 and the plurality of resin layers 21, 23, 27, 28, and 29.

Meanwhile, the plurality of redistribution lines 80, 82, 84, and 86 may include small sub-redistribution lines 70 and 73 and large sub-redistribution lines 71 and 74. For example, the small sub-redistribution lines 70 and 73 may be formed on the plurality of connection pads 41, 43, 45, and 47, and the large sub-redistribution lines 71 and 74 may be formed on the small sub-redistribution lines 70 and 73 to extend in the second direction (X-axis direction) and may be connected to the plurality of through lines 92, 94, and 96. Each of the small sub-redistribution lines 70 and 73 and each of the large sub-redistribution lines 71 and 74 may include a corresponding barrier layer and a corresponding conductive layer. For example, the first redistribution line 80 may include the first small sub-redistribution line 70 and the first large sub-redistribution line 71, the first small sub-redistribution line 70 may include the first barrier layer 50 and the first conductive layer 60, and the first large sub-redistribution line 71 may include the second barrier layer 51 and the second conductive layer 61.

Since the plurality of through lines 92, 94, and 96 and the plurality of redistribution lines 80, 82, 84, and 86 are provided to transmit electrical signals, they may be made of, for example, copper (Cu). However, the barrier layers 50, 51, 52, 53, and 54 may include a material other than copper, for example, titanium (Ti), to prevent the conductive layers 60, 61, 62, 63, and 64 from penetrating to outsides of the plurality of through lines 92, 94, and 96 and the plurality of redistribution lines 80, 82, 84, and 86.

The semiconductor package 101 may include a plurality of resin layers 21, 23, 27, 28, and 29. The plurality of resin layers 21, 23, 27, 28, and 29 may be formed on the wafer 10 and cover the plurality of semiconductor chips 40, 42, 44, and 46, the plurality of through lines 92, 94, and 96, and the plurality of redistribution lines 80, 82, 84, and 86 so they may not be exposed to the outside. Only the bump 100 formed on the fourth redistribution line 86 may be exposed to the outside to transmit/receive electrical signals or power to/from the outside.

The plurality of resin layers 21, 23, 27, 28, and 29 may be formed in multiple layers. For example, the first resin layer 21 may cover lateral surfaces and a bottom surface of the first semiconductor chip 40 while the first resin layer 21 may be formed to expose only a top surface of the first connection pad 41 on the first insulation layer 20. A top surface of the first resin layer 21 may be positioned on the same line with a top surface of the first small sub-redistribution line 70. The second resin layer 23 may be formed on the first resin layer 21, and a top surface of the second resin layer 23 may be positioned on the same line with a top surface of the first large sub-redistribution line 71. The first large sub-redistribution line 71 may be formed on the first resin layer 21. The third resin layer 27 may be formed on the second insulation layer 25, and may cover lateral surface and a top surface of the second semiconductor chip 43 and may surround the lateral surfaces of the first through line 92. A top surface of the third resin layer 27 may be positioned on the same line with a top surface of the first through line 92 and a top surface of the second small sub-redistribution line 73.

The second large sub-redistribution line 74 may be formed on the third resin layer 27, and the fourth resin layer 28 may be formed on lateral surfaces of the second large sub-redistribution line 74. A top surface of the second large sub-redistribution line 74 may be positioned on the same line with a top surface of the fourth resin layer 28. Resin layers surrounding the third and fourth semiconductor chips 44 and 46 may be formed to have the same shapes as the third and fourth resin layers 27 and 28 surrounding the second semiconductor chip 42. The fifth resin layer 29 may be formed on the fourth redistribution line 86 and may protect the semiconductor package 101 from external impacts.

The plurality of resin layers 21, 23, 27, 28, and 29 and the plurality of insulation layers 20, 25, 24, and 26 may be made of, for example, polyimide resin, but aspects of the present general inventive concept are not limited thereto.

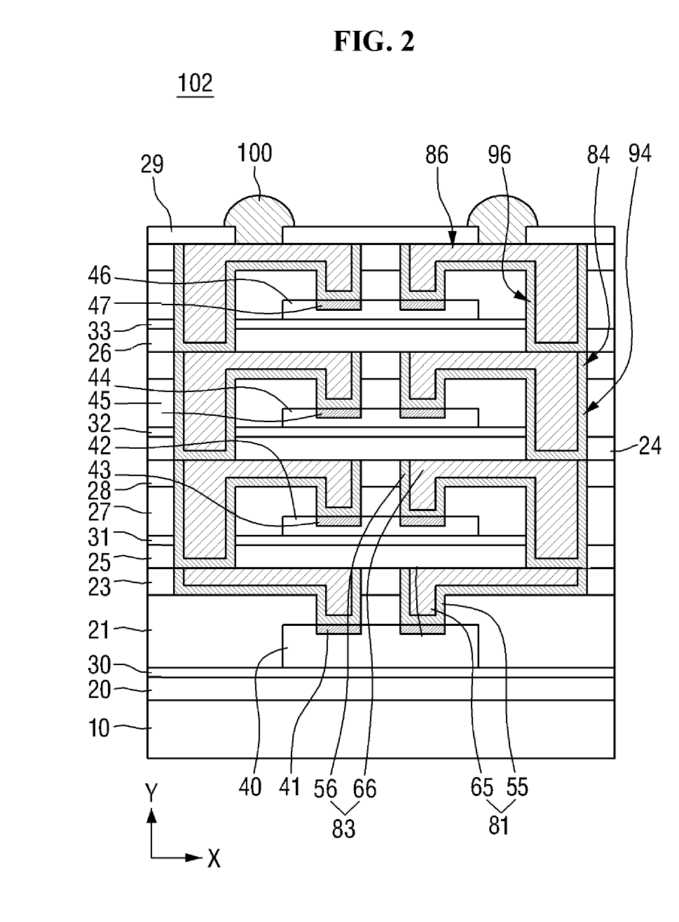

A semiconductor package 102 according to another embodiment of the inventive concept is described with reference to FIG. 2. Explanations of elements that are the same as those of the semiconductor package 101 are omitted, and the following description focuses on differences between the embodiment of the semiconductor package 102 illustrated in FIG. 2 and the embodiment of the semiconductor package 101 illustrated in FIG. 1.

FIG. 2 is a cross-sectional view of the semiconductor package 102 according to an embodiment of the inventive concept.

Referring to FIG. 2, the semiconductor package 102 may be different from the semiconductor package 101 with respect to the plurality of through lines 92, 94, and 96 and the plurality of redistribution lines 80, 82, 84, and 86. In the semiconductor package 101 illustrated in FIG. 1, the barrier layer 52 may be formed on the lateral surfaces and the bottom surfaces of the plurality of through lines 92, 94, and 96, and the barrier layers 50, 51, 53, and 54 may be formed on the lateral surfaces and bottom surfaces of the first and second small sub-redistribution lines 70 and 73 and the first and second large sub-redistribution lines 71 and 74. In contrast, in the semiconductor package 102 illustrated in FIG. 2, the plurality of through lines 92, 94, and 96 and the plurality of redistribution lines 80, 82, 84, and 86 may be integrally formed. For example, in the semiconductor package 102 illustrated in FIG. 2, since the first small sub-redistribution line 70 (see FIG. 1) and the first large sub-redistribution line 71 (see FIG. 1) may be integrally formed on the first semiconductor chip 40, a barrier layer 55 may be conformally formed on lateral surfaces and a bottom surface of a first redistribution line 81, and a conductive layer 65 may be formed on the barrier layer 55. Therefore, a barrier layer may not be formed between the first small sub-redistribution line 70 (see FIG. 1) and the first large sub-redistribution line 71 (see FIG. 1). The second redistribution line 82 (see FIG. 1) at both sides and on a top surface of the second semiconductor chip 42 and the first through line 92 (see FIG. 1) may also be integrally formed as a second redistribution line/first through line 83, and may include a barrier layer 56 and a conductive layer 66. Therefore, a barrier layer may not be formed between the first through line 92 (see FIG. 1) and the second large sub-redistribution line 74 (see FIG. 1), and between the second small sub-redistribution line 73 (see FIG. 1) and the second large sub-redistribution line 74 (see FIG. 1). Likewise, the second through line 94 and the third redistribution line 84 may be integrally formed, and the third through line 96 and the fourth redistribution line 86 may be integrally formed. The semiconductor package 102 illustrated in FIG. 2 may also be different from the semiconductor package 101 illustrated in FIG. 1 due to differences in methods of fabricating the semiconductor packages 101 and 102. A method of fabricating the semiconductor package 102 according to an embodiment of the inventive concept is described below.

A method of fabricating the semiconductor package 101 according to an embodiment of the inventive concept is described with reference to FIGS. 1 and 3 to 20.

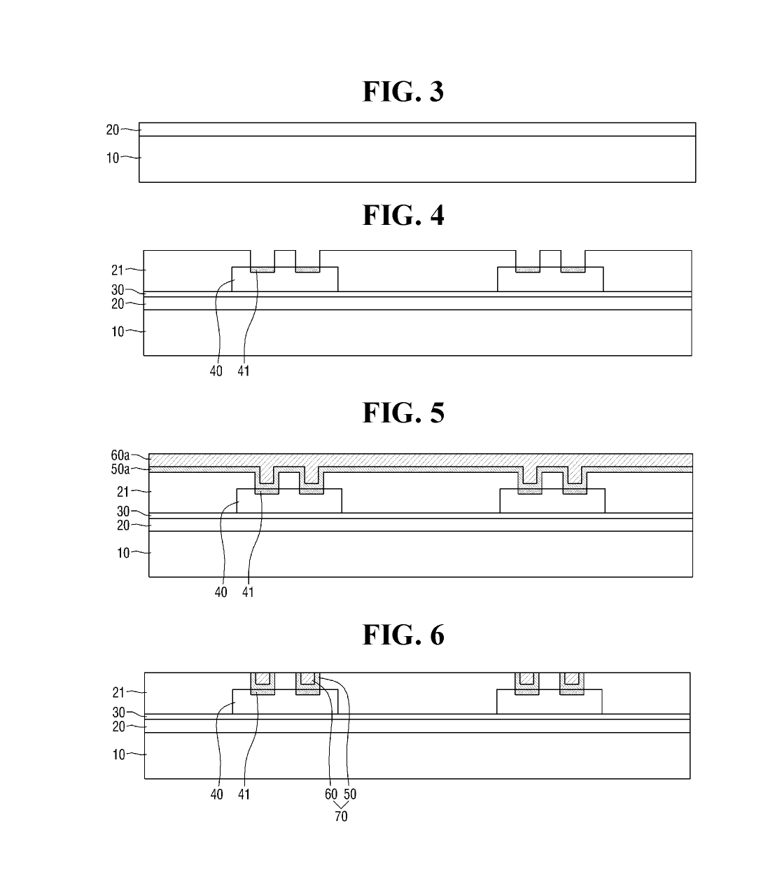

FIGS. 3 to 20 illustrate intermediate process operations that explain a method of fabricating the semiconductor package 101 according an embodiment of the inventive concept.

First, referring to FIG. 3, the first insulation layer 20 may be formed on the wafer 10.

Next, referring to FIG. 4, the first adhesive layer 30 may be formed on the first insulation layer 20, and a first semiconductor chip 40 may be formed on the first adhesive layer 30. Next, the first resin layer 21 may be formed to cover the first semiconductor chip. The first resin layer 21 may be formed to expose a top surface of the first connection pad 41 included in the first semiconductor chip 40. In order to expose the top surface of the first connection pad 41, the first semiconductor chip 40 may be entirely covered by the first resin layer 21, and the top surface of the first connection pad 41 may then be exposed by photolithography, for example.

Next, as illustrated in FIG. 5, a first barrier layer 50a and a first conductive layer 60a may be sequentially formed on the wafer 10.

Referring to FIG. 6, the first small sub-redistribution line 70 may be formed while a top surface of the first resin layer 21 may be exposed. Cutting or chemical mechanical polishing (CMP) may be employed, for example, to form the first small sub-redistribution line 70. The first small sub-redistribution line 70 may include the first barrier layer 50 conformally formed along lateral surfaces of the first resin layer 21 and a bottom surface of the first connection pad 41, and the first conductive layer 60 formed on the first barrier layer 50. A top surface of the first small sub-redistribution line 70 and the top surface of the first resin layer 21 may be coplanar.

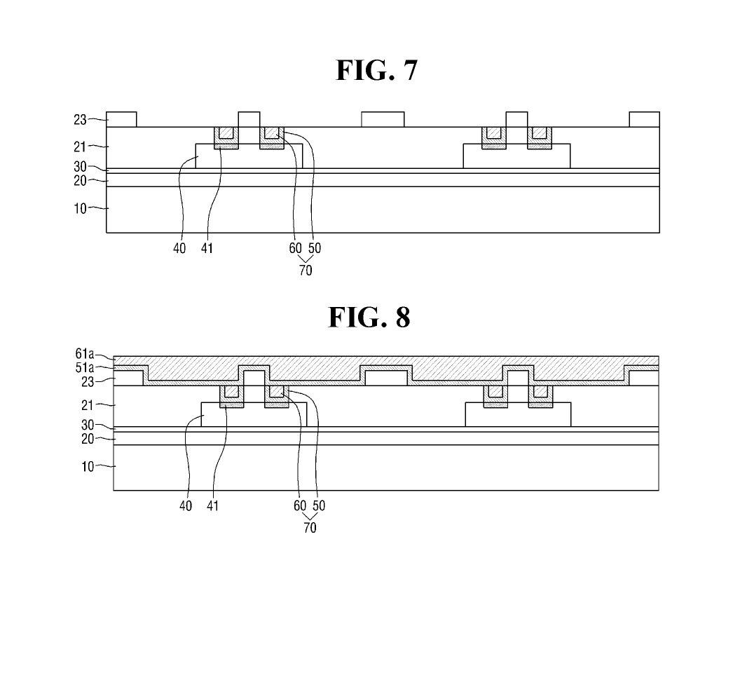

Next, referring to FIG. 7, the second resin layer 23 may be formed on the first resin layer 21. A portion of the first resin layer 21 and the top surface of the first small sub-redistribution line 70 may be exposed by patterning the second resin layer 23. The patterning may be performed by photolithography, for example.

Referring to FIG. 8, a barrier layer 51a and a conductive layer 61a may be sequentially formed on the wafer 10. The barrier layer 51a and the conductive layer 61a may be formed on the exposed top surface of the first connection pad 41 and the exposed top surface of the first resin layer 21.

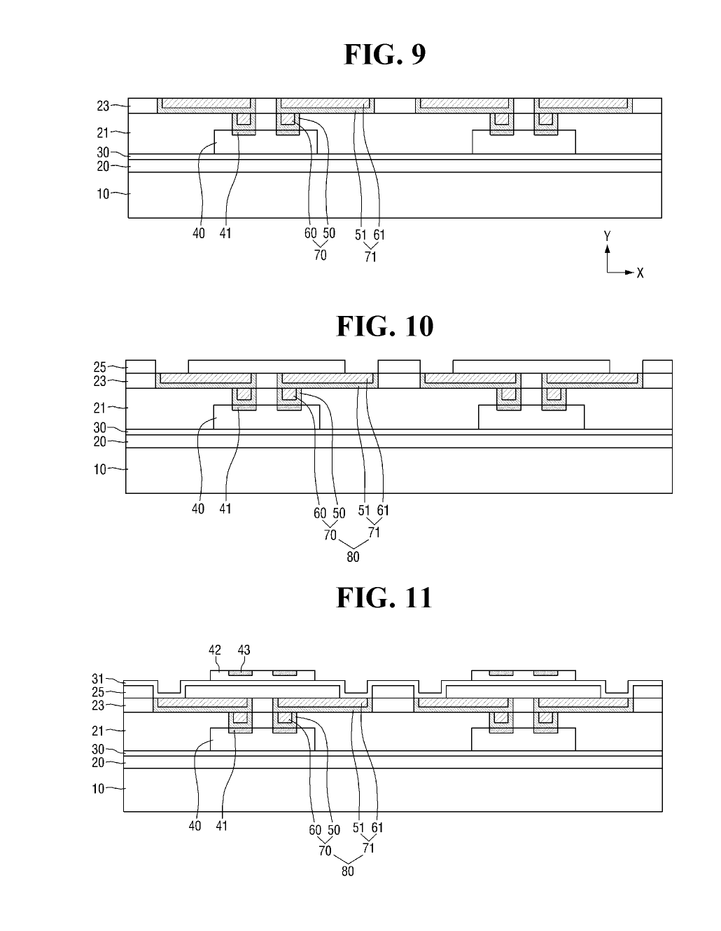

Referring to FIG. 9, the first large sub-redistribution line 71 may be formed by removing the barrier layer 51a and the conductive layer 61a formed on the second resin layer 23. Cutting or chemical mechanical polishing (CMP) may be used, for example, to remove the barrier layer 51a and the conductive layer 61a formed on the second resin layer 23. The first large sub-redistribution line 71 may include the second barrier layer 51 conformally formed along lateral surfaces of the second resin layer 23 and the top surface of the first small sub-redistribution line 70, and the second conductive layer 61 may be formed on the second barrier layer 51. The first large sub-redistribution line 71 may be formed to extend in the second direction (X-axis direction), and a top surface of the second resin layer 23 and a top surface of the first large sub-redistribution line 71 may be coplanar.

Consequently, the first and second conductive layers 60 and 61 that may be included in the first redistribution line 80 may not be brought into contact with the first and second resin layers 21 and 23 because of the first and second barrier layers 50 and 51.

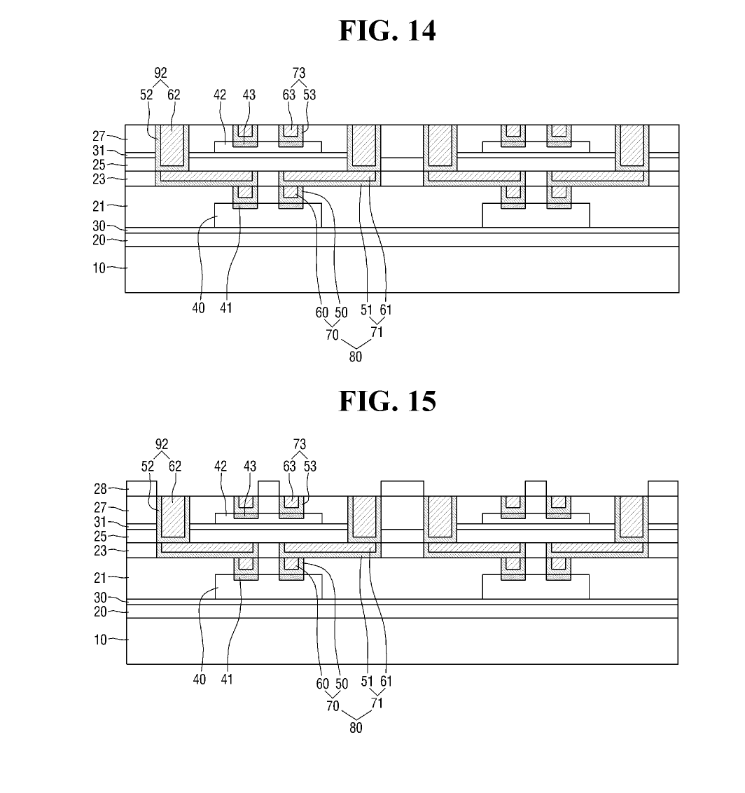

Referring to FIG. 10, the second insulation layer 25 may be formed on the second resin layer 23. The second insulation layer 25 may be formed to expose a portion of a top surface of the first redistribution line 80, the portion may be a potential area where the first through line 92 (see FIGS. 1 and 14) may be to be formed. The portion of the top surface of the first redistribution line 80 may be exposed by photolithography, for example.

Referring to FIG. 11, the second adhesive layer 31 may be formed on the second resin layer 23. Next, the second semiconductor chip 42 may be formed on the second adhesive layer 31. The second connection pad 44 may be arranged on a top surface of the second semiconductor chip 42.

In FIG. 11, after the portion of the top surface of the first redistribution line 80 is exposed, the second adhesive layer 31 may be formed. However, the portion of the top surface of the first redistribution line 80 may be exposed to form the second adhesive layer 31 on the second insulation layer 25 and then the same may be patterned, for example.

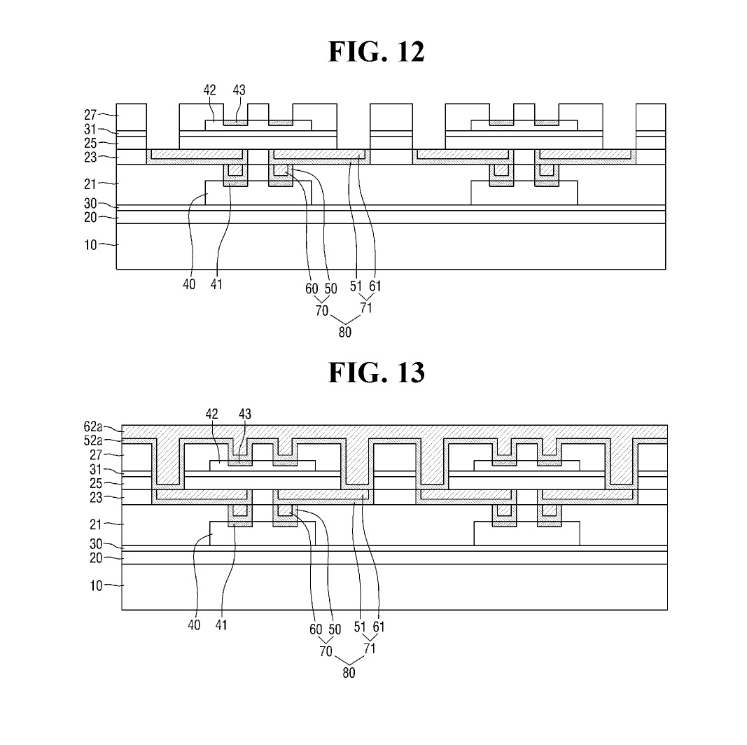

Referring to FIG. 12, the third resin layer 27 may be formed to cover the second semiconductor chip 42 and may be formed to expose the portion of the top surface of the first redistribution line 80 and the top surface of the second connection pad 43. The portion of the top surface of the first redistribution line 80 and the top surface of the second connection pad 43 may be exposed by photolithography, for example. The second adhesive layer 31 formed on the portion of the top surface of the first redistribution line 80 may also be removed by photolithography, for example.

Referring to FIG. 13, a barrier layer 52a and a conductive layer 62a may be sequentially formed on the wafer 10. The barrier layer 52a and the conductive layer 62a may be formed on the portion of the top surface of the first redistribution line 80 and on the top surface of the second connection pad 43.

Referring to FIG. 14, the first through line 92 and the second small sub-redistribution line 73 may be formed by removing the barrier layer 52a and the conductive layer 62a formed on the third resin layer 27. The first through line 92 may be formed on the portion of the top surface of the first redistribution line 80, and the second small sub-redistribution line 73 may be formed on the top surface of the second connection pad 43. Cutting or chemical mechanical polishing (CMP) may be employed, for example, to remove the barrier layer 52a and the conductive layer 62a formed on the third resin layer 27. The first through line 92 may include the third barrier layer 52 conformally formed on lateral surfaces of the third resin layer 27 and the second insulation layer 25 and the portion of the top surface of the first redistribution line 80, and the third conductive layer 62 formed on the third barrier layer 52.

The second small sub-redistribution line 73 may include the fourth barrier layer 53 conformally formed along the lateral surfaces of the third resin layer 27 and the top surface of the second connection pad 43, and the fourth conductive layer 63 formed on the fourth barrier layer 53.

The first through line 92 and the second small sub-redistribution line 73 may be positioned on the same plane with the top surface of the third resin layer 27.

Referring to FIG. 15, the fourth resin layer 28 may be formed on the third resin layer 27 to expose the portion of the top surface of the first redistribution line 80, the top surface of the second connection pad 43, and the third resin layer 27 formed between the top surface of the first redistribution line 80 and the second connection pad 43. The fourth resin layer 28 may be patterned by photolithography, for example.

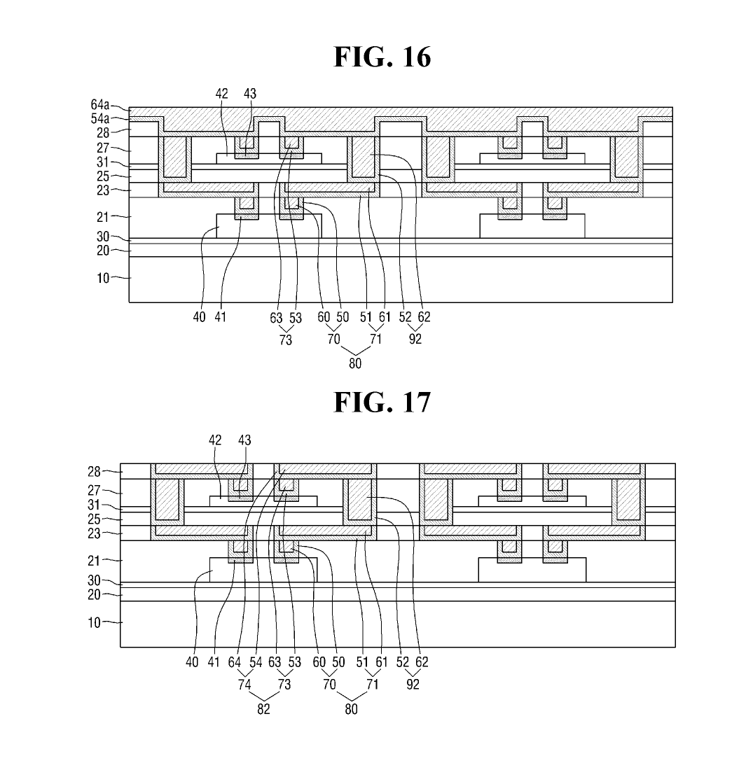

Referring to FIG. 16, a barrier layer 54a and a conductive layer 64a may be sequentially formed on the wafer 10.

Referring to FIG. 17, the second large sub-redistribution line 74 may be formed by removing the barrier layer 54a and the conductive layer 64a formed on the fourth resin layer 28. That is to say, the second large sub-redistribution line 74 may be formed on the first through line 92, the top surface of the second small sub-redistribution line 73, and the exposed third resin layer 27 between the first through line 92 and the top surface of the second connection pad 43. The second large sub-redistribution line 74 may include the fifth barrier layer 54 and the fifth conductive layer 64 conformally formed along the lateral surfaces of the fourth resin layer 28, the top surface of the first through line 92, the exposed top surface of the third resin layer 27, and the top surface of the second small sub-redistribution line 73. A top surface of the second large sub-redistribution line 74 and a top surface of the fourth resin layer 28 may be coplanar.

Cutting or chemical mechanical polishing (CMP) may be employed, for example, to remove the barrier layer 54a and the conductive layer 64a formed on the fourth resin layer 28.

Consequently, the third conductive layer 62 included in the first through line 92 may not be brought into contact with the second insulation layer 25 and the third resin layer 27 because of the third barrier layer 52. The fourth and fifth conductive layers 63 and 64 included in the second redistribution line 82 may not be brought into contact with the third and fourth resin layers 27 and 28 because of the fourth and fifth barrier layers 53 and 54.

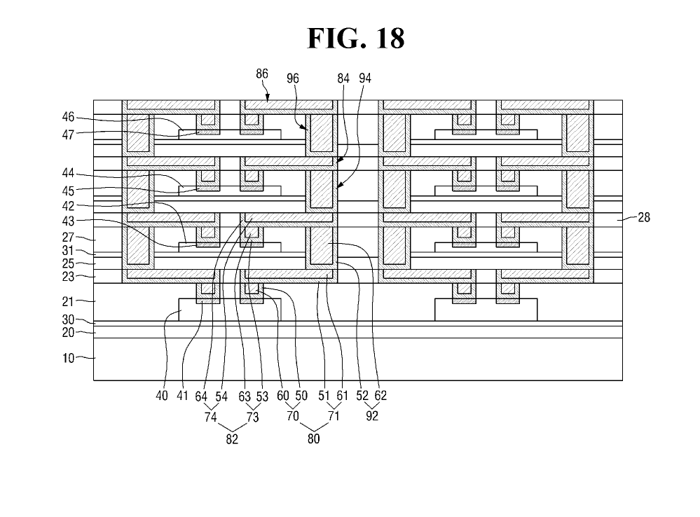

As illustrated in FIG. 18, the third and fourth semiconductor chips 44 and 46, the third and fourth connection pads 45 and 47, the second and third through lines 94 and 96, and the third and fourth redistribution lines 84 and 86 may be formed by the same method as described above with reference to FIGS. 10 to 17. The first to third through lines 92, 94, and 96 may be arranged in a line, and the first to fourth redistribution lines 80, 82, 84, and 86 may be vertically connected to the first to third through lines 92, 94, and 96.

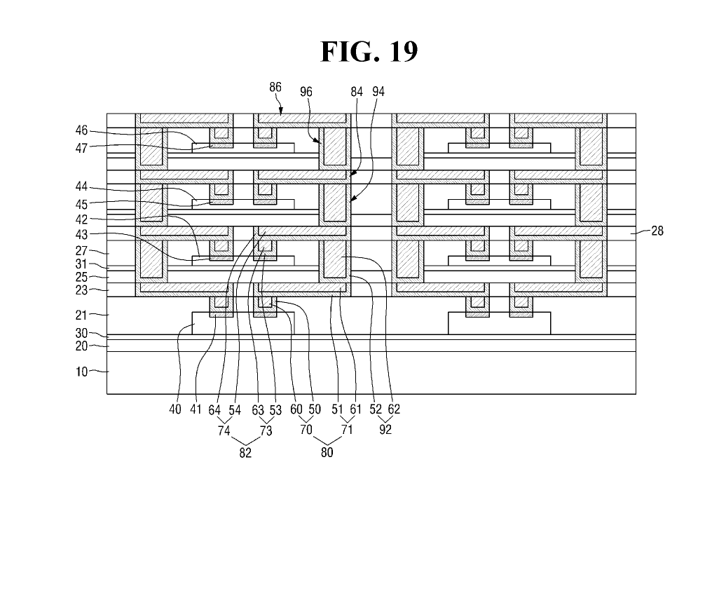

Next, referring to FIG. 19, the fifth resin layer 29 may be formed on the fourth redistribution line 86. For example, the fifth resin layer 29 may be patterned to expose the portion of the top surface of the fourth redistribution line 86. The patterning may be performed by photolithography, for example.

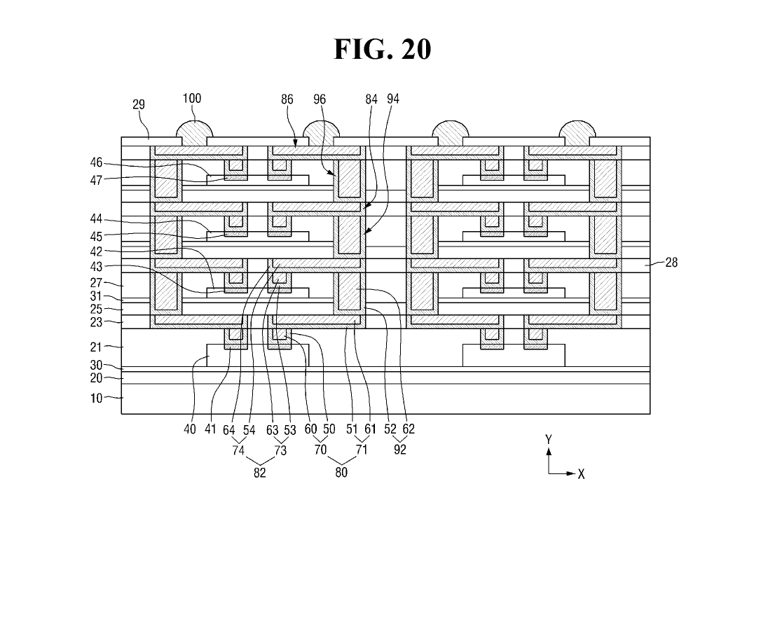

Referring to FIG. 20, bumps 100 may be formed on the exposed fourth redistribution line 86. The bumps 100 may allow the semiconductor package 101 to transmit/receive electrical signals or power to/from an external device (not illustrated).

In addition, a portion of the wafer 10 may be cut to adjust a thickness of the semiconductor package 101, thereby forming the wafer 10 illustrated in FIG. 20.

Next, cutting may be performed in the first direction (Y-axis direction) from the wafer 10 to the fifth resin layer 29, thereby forming the semiconductor package 101 illustrated in FIG. 1.

In the method of fabricating the semiconductor package 101 according an embodiment of the inventive concept, a plurality of semiconductor chips 40, 42, 44, and 46 may be sequentially stacked to form the semiconductor package 101. Because the plurality of semiconductor chips 40, 42, 44, and 46 may be sequentially stacked, it may not be necessary to separately form a through-silicon via (TSV) in the plurality of semiconductor chips 40, 42, 44, and 46 to electrically connect the plurality of semiconductor chips 40, 42, 44, and 46 to each other. Therefore, the plurality of semiconductor chips 40, 42, 44, and 46 may be fabricated at reduced sizes, compared with semiconductor chips fabricated with TSVs formed therein.

In addition, in the method of fabricating the semiconductor package 101 according an embodiment of the inventive concept, because the redistribution lines 80, 82, 84, and 86, the through lines 92, 94, and 96, etc. may be sequentially formed in multiple layers, it may not be necessary to perform a process of etching the resin layers 21, 23, 27, 28, and 29 or the insulation layers 20, 25, 24, and 26. In addition, additional processes to form wirings of the respective semiconductor chips 40, 42, 44, and 46 may not be required. Therefore, the cost and time required to fabricate the semiconductor package 101 may be reduced.

A method of fabricating the semiconductor package 102 according another embodiment of the inventive concept is described with reference to FIGS. 2 and 21 to 24. Explanations of operations that are the same as those of the method of fabricating the semiconductor package 101 are omitted, and the following description focuses on differences between the method of fabricating the semiconductor package 102 illustrated in FIGS. 2 and 21 to 24 and the method of fabricating the semiconductor package 101 illustrated in FIGS. 1 and 3 to 20.

In the method of fabricating the semiconductor package 102 according another embodiment of the inventive concept, the plurality of redistribution lines 80, 82, 84, and 86 and the plurality of through lines 92, 94, and 96 may be integrally formed. For example, referring to FIG. 21, after the first resin layer 21 may be formed to cover the first semiconductor chip 40 may be formed to expose the top surface of the first connection pad 41, the first small sub-redistribution line 70 (see FIG. 6) is not formed. Instead, the second resin layer 23 may be formed to expose the top surface of the first connection pad 41 and a portion of the top surface of the first resin layer 21 may be formed on the first resin layer 21. Next, as illustrated in FIG. 22, the first redistribution line 81 may be formed between the first resin layer 21 and the second resin layer 23. The first redistribution line 81 may include the barrier layer 55 conformally formed along lateral surfaces of the second resin layer 23, the top and lateral surfaces of the first resin layer 21, and the top surface of the first connection pad 41, and the conductive layer 65 formed on the barrier layer 55. The top surface of the first redistribution line 81 and the top surface of the second resin layer 23 may be coplanar.

Next, the second insulation layer 25, the second adhesive layer 31, the second semiconductor chip 42 and the third resin layer 27 may be formed. The second insulation layer 25, the second adhesive layer 31, the second semiconductor chip 42 and the third resin layer 27 may be formed by the same methods as those used in the method of fabricating the semiconductor package 101 according to the embodiment illustrated in FIG. 1.

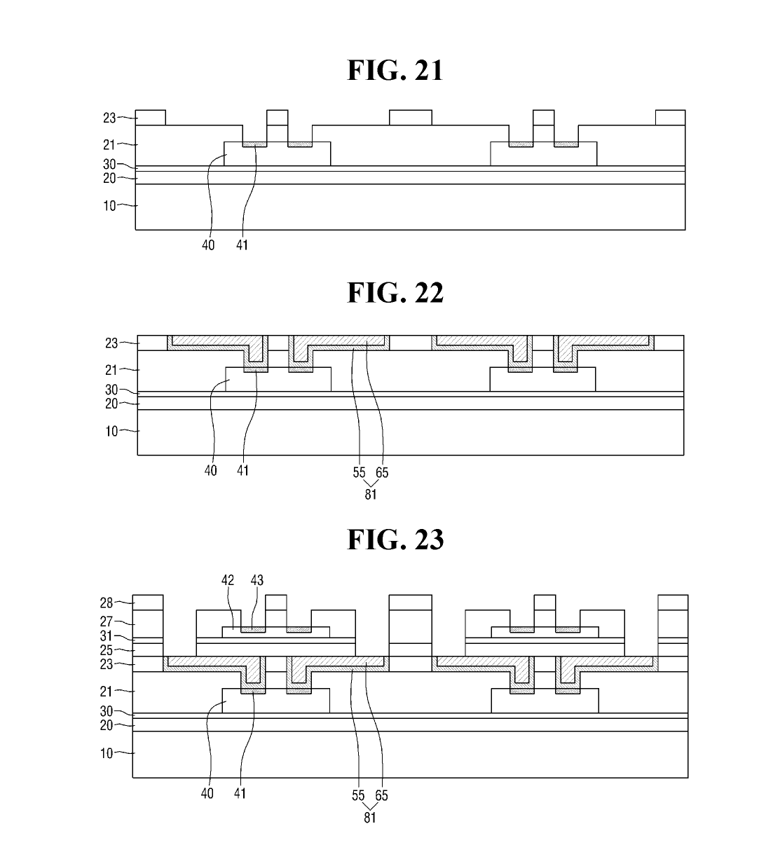

Referring to FIG. 23, after the third resin layer 27 is formed, the fourth resin layer 28 may be formed on the third resin layer 27 without forming the first through line 92 (see FIG. 14) and the second small sub-redistribution line 73 (see FIG. 14). The fourth resin layer 28 may be formed to expose a portion of the top surface of the first redistribution line 81, a top surface of the second connection pad 43, and the third resin layer 27 between the top surface of the first redistribution line 81 and the second connection pad 43.

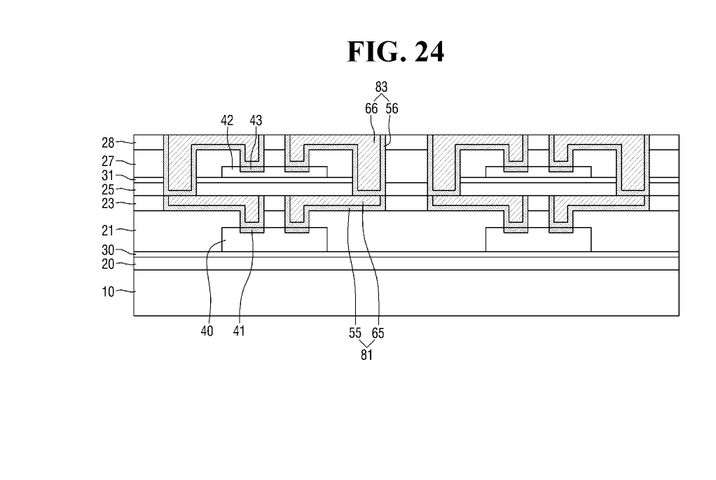

Next, as illustrated in FIG. 24, the barrier layer 56 may be conformally formed between each of the second insulation layer 25, the third resin layer 27, and the fourth resin layer 28, and the conductive layer 66 may be formed on the barrier layer 56. A top surface of the conductive layer 66 and a top surface of the fourth resin layer 28 may be coplanar. Eventually, the first through line 92 (see FIG. 17) and the second redistribution line 82 (see FIG. 17) may be integrally formed.

The third and fourth semiconductor chips 44 and 46 may be stacked in the same manner as in the method of fabricating the semiconductor package 102 illustrated in FIGS. 22 to 24, and the third and fourth redistribution lines 84 and 86. and the second and third through lines 94 and 96 may then be formed along with the bumps 100, thereby forming the semiconductor package 102 illustrated in FIG. 2.

The method of fabricating the semiconductor package 102 illustrated in FIGS. 2 and 21 to 24 may have a reduced number of fabrication process steps compared with the method of fabricating the semiconductor package 101 illustrated in FIGS. 1 and 3 to 20, thereby further reducing the cost and time required to fabricate the semiconductor package 102.

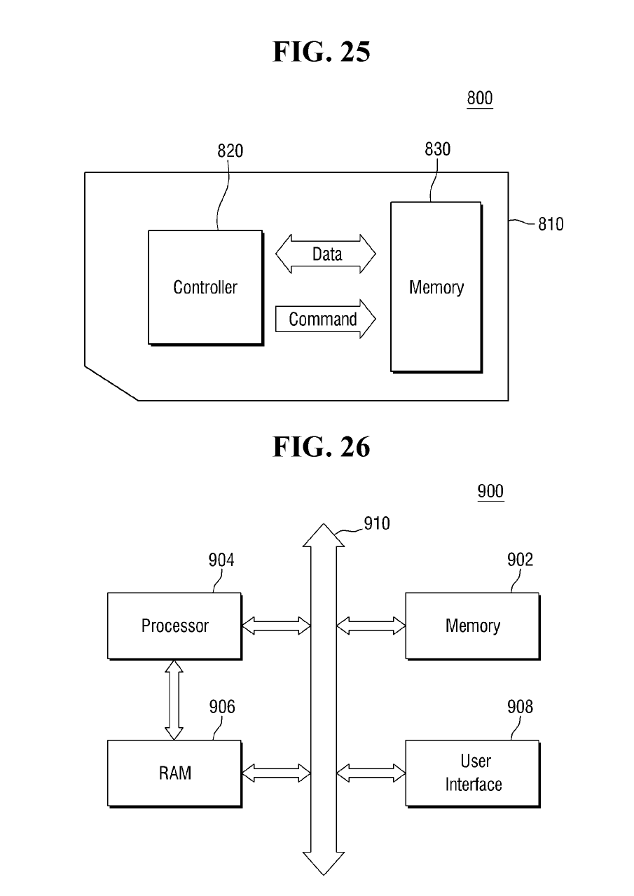

FIG. 25 is a block diagram that illustrates a memory card 800 that incorporates semiconductor packages according to an embodiment of the inventive concept.

Referring to FIG. 25, the memory card 800 may include a controller 820 and a memory 830 in a housing 810. The controller 820 and the memory 830 may exchange electrical signals. For example, the memory 830 and the controller 820 may exchange data in response to a command of the controller 820. Accordingly, the memory card 800 may store the data in the memory 830 or may output the data from the memory 830 to the outside.

The controller 820 or the memory 830 may include a semiconductor package according to the inventive concept (not illustrated). For example, the controller 820 may include a system in a package (SIP) and the memory 830 may include a multi-chip package (MCP). Meanwhile, the controller 820 and/or the memory 830 may be provided, for example, as a stack package (SP).

The memory card 800 may be used as a data storage medium of a variety of portable devices. For example, the memory card 800 may include a multi-media card (MMC) or a secure digital (SD) card.

FIG. 26 is a block diagram that illustrates an electronic system 900 that incorporates a semiconductor package according to an embodiment of the inventive concept.

Referring to FIG. 26, the electronic system 900 may employ the semiconductor packages according to the above-described embodiments of the inventive concept. For example, the electronic system 900 may include a memory system 902, a processor 904, a random-access memory (RAM) 906, and a user interface 908.

The memory system 902, the processor 904, the RAM 906, and the user interface 908 may perform data communication with each other using a bus 910.

The processor 904 may execute a program and may control the electronic system 900, and the RAM 906 may be used as an operation memory of the processor 904. The processor 904 and the RAM 906 may be packaged as a single semiconductor device or a semiconductor package using the methods of fabricating the semiconductor packages according to the above-described embodiments of the inventive concept.

The user interface 908 may be used to input/output data to/from the electronic system 900. The memory system 902 may store codes for the operation of the processor 904, the data processed by the processor 904, and/or externally input data.

The memory system 902 may include a separate controller (not illustrated) to drive the memory system 902, and may further include an error correction block (not illustrated). The error correction block may be configured to detect and correct an error of the data stored in the memory system 902 by using an error correction code (ECC).

In an embodiment, memory system 902 may be integrated into one semiconductor device (not illustrated) to constitute a memory card (see, for example, FIG. 25). For example, the memory system 902 may be integrated into one semiconductor device to constitute a memory card such as, for example, a personal computer memory card international association (PCMCIA) card, a compact flash (CF) card, a smart media card, a memory stick, a multimedia card (e.g., MultiMediaCard (MMC), Reduced-Size MultiMediaCard (RS-MMC), and Micro Size MultiMediaCard (MMC-micro)), a secure digital (SD) card (e.g., Secure Digital (SD), Mini Size Secure Digital (mini-SD), Micro Size Secure Digital (micro-SD), and Secure Digital High Capacity (SDHC)), or a universal flash storage (UFS) card.

The electronic system 900 illustrated in FIG. 26 may be applied to electronic controllers (not illustrated) of various electronic devices (not illustrated).

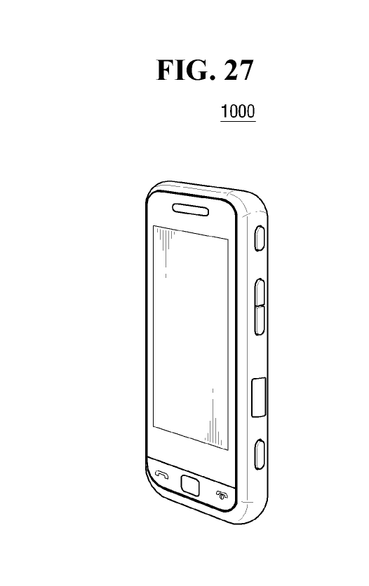

FIG. 27 illustrates an example of the electronic system 900 used for a smart phone 1000. As illustrated in FIG. 27, in a case where the electronic system 900 (see FIG. 26) is used for the smart phone 1000, the electronic system 900 (see FIG. 26) may be, for example, an application processor (AP), but aspects of the present general inventive concept are not limited thereto.

In an embodiment, the electronic system 900 (see FIG. 26) may be incorporated into a variety of different types of devices, such as, for example, computers, ultra mobile personal computers (UMPCs), work stations, net-books, personal digital assistants (PDAs), portable computers, web tablets, wireless phones, mobile phones, smart phones, e-books, portable multimedia players (PMPs), portable game consoles, navigation devices, black boxes, digital cameras, three-dimensional televisions, digital audio recorders, digital audio players, digital video recorders, digital video players, devices configured to transmit/receive information in wireless environments, one of various electronic devices constituting a home network, one of various electronic devices constituting a computer network, one of various electronic devices constituting a telematics network, radio-frequency identification (RFID) devices, and/or computing systems.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor package, comprising:
a wafer;
a plurality of semiconductor chips each having a connection pad and being stacked on the wafer;
a plurality of resin layers formed to expose top surfaces of the connection pads and to cover lateral surfaces and top surfaces of the plurality of semiconductor chips;
a plurality of through lines formed in at least one side of opposite sides of each of the plurality of semiconductor chips, to be spaced apart from the plurality of semiconductor chips, and to extend in a first direction; and
a plurality of redistribution lines arranged between the plurality of through lines, formed to extend in a second direction on the resin layers, and connected to the connection pads,
wherein the plurality of through lines and the plurality of redistribution lines include barrier layers formed on lateral surfaces and bottom surfaces of the through lines and the redistribution lines, and conductive layers formed on the barrier layers.

2. The semiconductor package of claim 1, wherein the first direction and the second direction are perpendicular to each other.

3. The semiconductor package of claim 1, further comprising a plurality of insulation layers formed on bottom surfaces of the plurality of semiconductor chips.

4. The semiconductor package of claim 3, further comprising adhesive layers formed between the insulation layers and the semiconductor chips.

5. The semiconductor package of claim 3, wherein, of the plurality of insulation layers, an insulation layer formed on a top surface of the wafer includes a thermal interface material.

6. The semiconductor package of claim 1, wherein:
at least one of the plurality of redistribution lines includes a first sub-redistribution line and a second sub-redistribution line, and
the barrier layers are formed on the lateral surfaces and the bottom surfaces of the first sub-redistribution line and the second sub-redistribution line.

7. The semiconductor package of claim 1, wherein the through lines and the redistribution lines include copper.

8. The semiconductor package of claim 7, wherein the barrier layers include titanium.

9. A method of fabricating a semiconductor package, comprising:
providing a first semiconductor chip connected to a first redistribution line;
forming a first insulation layer that exposes a portion of a top surface of the first redistribution line;
forming a second semiconductor chip on the first insulation layer, the second semiconductor chip having a first connection pad arranged on a top surface of the second semiconductor chip;
forming a first resin layer that covers the second semiconductor chip and exposes the portion of the top surface of the first redistribution line and a top surface of the first connection pad;
forming, on the first resin layer, a second resin layer that exposes the portion of the top surface of the first redistribution line, the top surface of the first connection pad, and the first resin layer between the top surface of the first redistribution line and the first connection pad;
forming through lines on the top surface of the first redistribution line; and
forming a second redistribution line on the through lines, the top surface of the first connection pad, and the first resin layer.

10. The method of claim 9, wherein the through lines do not overlap the first semiconductor chip and the second semiconductor chip.

11. The method of claim 9, wherein the forming the through lines and the forming the second redistribution line comprise:
forming a barrier layer on the portion of the top surface of the first redistribution line and the top surface of the first connection pad; and
forming a conductive layer on the barrier layer.

12. The method of claim 9, wherein:
the second redistribution line includes a first sub-redistribution line and a second sub-redistribution line, and
the forming the through lines and the forming the second redistribution line further comprise,
after the forming the first resin layer, forming the through lines on the top surface of the first redistribution line and forming the first sub-redistribution line on the top surface of the first connection pad, and,
after the forming the second resin layer, forming the through lines on the first sub-redistribution line and the third resin layer.

13. The method of claim 9, before the providing the first semiconductor chip, further comprising:
forming a second insulation layer on the wafer;
forming the first semiconductor chip on the second insulation layer, the first semiconductor chip having a second connection pad arranged on a top surface of the first semiconductor chip;
forming a third resin layer that covers the first semiconductor chip and exposes a top surface of the second connection pad;
forming, on the third resin layer, a fourth resin layer that exposes the top surface of the second connection pad and a portion of a top surface of the third resin layer; and
forming the first redistribution line on the top surface of the second connection pad and a top surface of the third resin layer.

14. The method of claim 13, further comprising:
after the forming the second insulation layer, forming a first adhesive layer on the second insulation layer; and
after the forming the first insulation layer, forming a second adhesive layer on the first insulation layer.

15. The method of claim 13, wherein:
the first redistribution line includes a third sub-redistribution line and a fourth sub-redistribution line, and
the forming the first redistribution line comprises
forming the third sub-redistribution line on the top surface of the second connection pad after the forming the third resin layer, and
forming the fourth sub-redistribution line on the top surface of the third resin layer after the forming the fourth resin layer.

16. A semiconductor package, comprising:
a first semiconductor chip formed on a wafer and connected to a first redistribution line;
a second semiconductor chip formed on the first semiconductor chip and connected to a second redistribution line; and
a through line spaced apart from the first semiconductor chip and the second semiconductor chip and connected to the first redistribution line and the second redistribution line;
wherein at least one of the first redistribution line, the second distribution line, and the through line includes a barrier layer on all surfaces except for an upper surface.

17. The semiconductor package of claim 16, wherein the barrier layer includes titanium.

18. The semiconductor package of claim 16 wherein at least one of the first semiconductor chip and the second semiconductor chip excludes a through-silicon via.

19. The semiconductor package of claim 16, wherein at least one of the first semiconductor chip and the second semiconductor chip is formed on an adhesive layer and includes a resin layer on all surfaces of the at least one of the first semiconductor chip and the second semiconductor chip except for an upper surface of the at least one of the first semiconductor chip and the second semiconductor chip, the adhesive layer formed on an insulation layer.

20. The semiconductor package of claim 16, wherein:
at least one of the first redistribution line and the second redistribution line includes a first sub-redistribution line and a second sub-redistribution line; and
each of the first sub-redistribution line and the second sub-redistribution line includes the barrier layer on all surfaces of each of the first sub-redistribution line and the second sub-redistribution line except for an upper surface of each of the first sub-redistribution line and the second sub-redistribution line.
